(19) United States
(12) Patent Application Publication
(10) Pub. No.: US 2026/0191098 A1
(43) Pub. Date: Jul. 2, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chia-Pu LIANG, Taichung City (TW); Jun-Yan LI, Taichung City (TW); Pei-Hsuan KE, Taichung City (TW); Chia-Hsi HSIEH, Taichung City (TW); Shu-Ping YANG, Taichung City (TW)

(73) Assignee: SILICONWARE PRECISION INDUSTRIES CO., LTD., Taichung City (TW)

(21) Appl. No.: 19/206,150

(22) Filed: May 13, 2025

(30) Foreign Application Priority Data
Dec. 30, 2024 (TW) 113151523

(51) Int. Cl. H01L 25/16; H01L 23/31; H01L 23/49; H01L 23/538; H01L 25/00

(52) U.S. Cl. CPC H10W 90/00; H10W 70/611; H10W 70/65; H10W 72/50; H10W 74/111

(57) ABSTRACT

An electronic package and a manufacturing method thereof are provided, in which a carrying structure is provided, and an optoelectronic device is disposed on the carrying structure. The optoelectronic device includes a package module, a semiconductor component disposed in the package module, and an optical component connected to the package module. The optical component and an optical element (optical fiber or optical fiber connector) connected to the optical component are stably in contact with and bonded to the carrying structure. Therefore, the support and protection of the optical fiber are enhanced to ensure stable signal transmission of the optical fiber.

### BACKGROUND

### 1. Technical Field

The present disclosure relates to a semiconductor device, and more particularly, to an electronic package having an optoelectronic device and a manufacturing method thereof.

### 2. Description of Related Art

With the vigorous development of the electronics industry, electronic products are gradually progressing towards multi-functionality and high performance. The current fifth generation (5G) communication technology has been applied to various fields such as Internet of Things (IoT), Industrial Internet of Things (IIoT), cloud, artificial intelligence (AI), autonomous cars, and medical care. With the expansion of the application level, a large amount of data is generated that needs to be efficiently transmitted, computed and stored. In particular, there is a huge demand for data transmission. Therefore, the industry has begun to use “light” instead of “electricity” as the carrier of data transmission to increase the transmission capacity, efficiency, or distance, and reduce energy consumption during the transmission process. In this context, co-packaged optics has become the development trend of future semiconductor and packaging technology.

FIG. 1 is a schematic cross-sectional view of a conventional semiconductor package 1 of co-packaged optics. An electronic component 11, an electronic integrated circuit component 12, and a photonic integrated circuit component 13 bonded onto the electronic integrated circuit component 12 are respectively disposed on a substrate 10 of the semiconductor package 1. One side end of the photonic integrated circuit component 13 is connected to an optical element (optical fiber or optical fiber connector) 14.

However, in the semiconductor package 1, the optical element (optical fiber or optical fiber connector) 14 is connected to and suspended from the photonic integrated circuit component 13. Such suspension may cause problems such as poor stability of the connector, easy breakage of the optical element 14, and easy loosening of the optical fiber at the connecting position.

Therefore, how to overcome the above-mentioned drawbacks of the prior art has become an urgent issue to be solved.

### SUMMARY

In view of the various deficiencies of the prior art, the present disclosure provides an electronic package, which comprises: a carrying structure having a first surface and a second surface opposite to the first surface; an optoelectronic device disposed on the first surface of the carrying structure and electrically connected to the carrying structure, wherein the optoelectronic device includes a package module, a semiconductor component disposed in the package module, and an optical component connected to the package module, wherein a side of the optoelectronic device having the optical component is bonded to the carrying structure, and another side of the optoelectronic device having the package module faces a direction away from the carrying structure; and an electronic component disposed on the first surface of the carrying structure and electrically connected to the carrying structure.

The present disclosure further provides a method of manufacturing an electronic package, the method comprises: providing a carrying structure having a first surface and a second surface opposite to the first surface; disposing an optoelectronic device on the first surface of the carrying structure, and electrically connecting the optoelectronic device to the carrying structure, wherein the optoelectronic device includes a package module, a semiconductor component disposed in the package module, and an optical component connected to the package module, wherein a side of the optoelectronic device having the optical component is in contact with and bonded to the carrying structure, and another side of the optoelectronic device having the package module faces a direction away from the carrying structure; and disposing an electronic component on the first surface of the carrying structure, and electrically connecting the electronic component to the carrying structure.

In the aforementioned electronic package and method, the first surface of the carrying structure is formed with a groove, and the optoelectronic device is accommodated in the groove.

In the aforementioned electronic package and method, the package module is of a fan-out package-on-package structure, the semiconductor component is an electronic integrated circuit component, and the optical component is an optical chip or an optical chip module.

In the aforementioned electronic package and method, the optical chip module includes a coupler, an optical chip, a total reflection mirror, or an optical fiber array unit.

In the aforementioned electronic package and method, the optical component is bonded to an optical element.

In the aforementioned electronic package and method, the present disclosure further comprises electrically connecting the carrying structure to the optoelectronic device via a plurality of bonding wires.

In the aforementioned electronic package and method, an end of each of the plurality of bonding wires is connected to the first surface of the carrying structure, and another end of each of the plurality of bonding wires is connected to an electrical contact on a surface of the package module of the optoelectronic device.

In the aforementioned electronic package and method, the electronic component is bonded and electrically connected to the carrying structure via a carrier.

In the aforementioned electronic package and method, the carrier is bonded and electrically connected to the first surface of the carrying structure via a plurality of conductive components.

In the aforementioned electronic package and method, the present disclosure further comprises forming an encapsulation layer on the carrying structure to encapsulate the electronic component and the optoelectronic device.

As can be seen from the above, in the electronic package and the manufacturing method thereof of the present disclosure, the optoelectronic device is placed on the carrying structure in an inverted manner, so that the optical component of the optoelectronic device and the connected optical element are placed in the groove at the edge of the carrying structure. At the same time, the electrical contacts on the surface of the package module of the inverted optoelectronic device are electrically connected to the carrying structure via the bonding wires. Therefore, the support and protection of the optical fiber are enhanced, so that the signal transmission of the optical element can be stable, thereby solving the problems of optical element contact breakage and signal transmission abnormality in the conventional structure.

### BRIEF DESCRIPTION OF THE DRAWINGS

FIG. 1 is a schematic cross-sectional view of a conventional semiconductor package of co-packaged optics.

FIG. 2A to FIG. 2E are schematic cross-sectional views illustrating a method of manufacturing an electronic package according to the present disclosure.

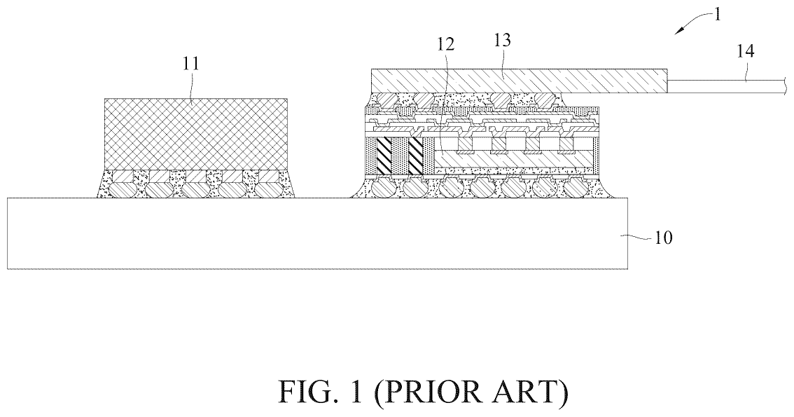

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “third,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

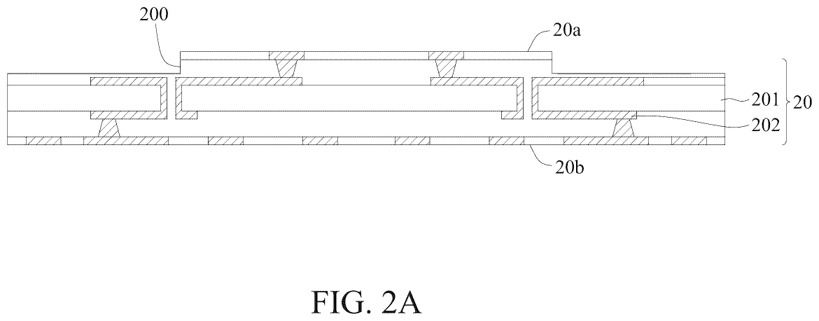

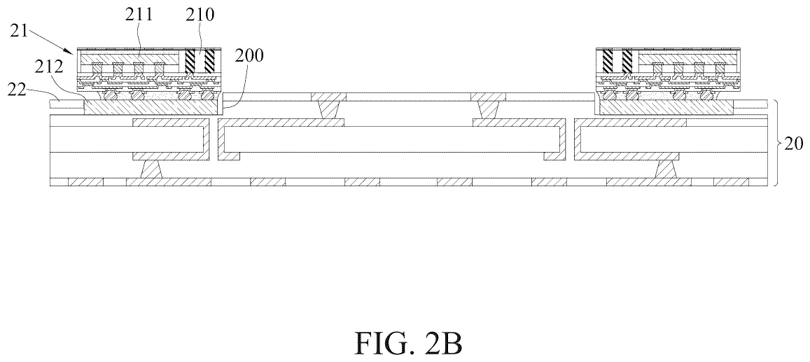

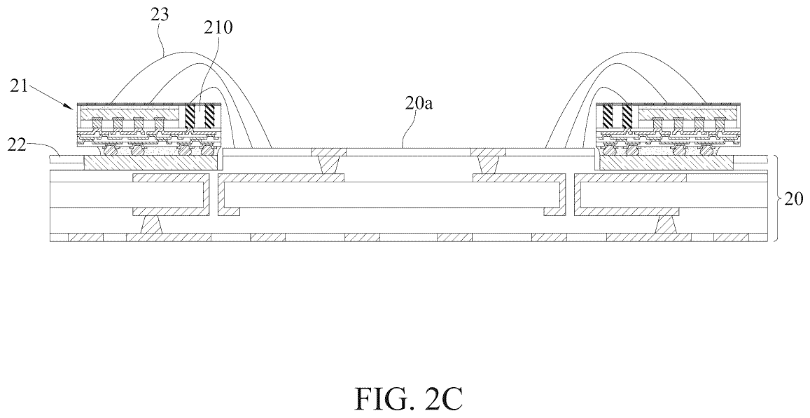

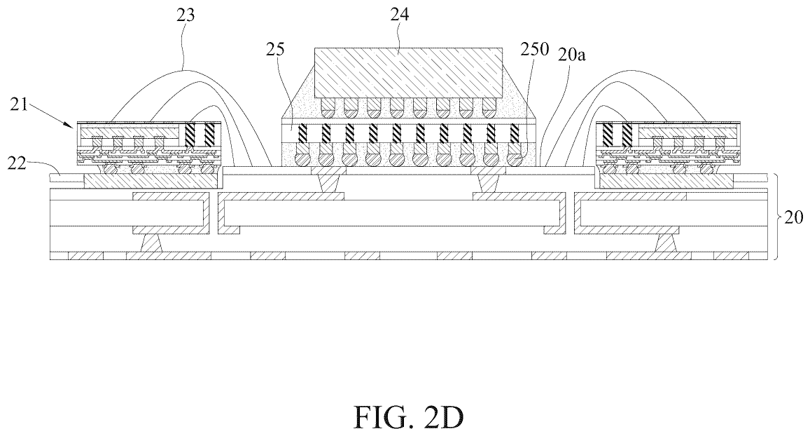

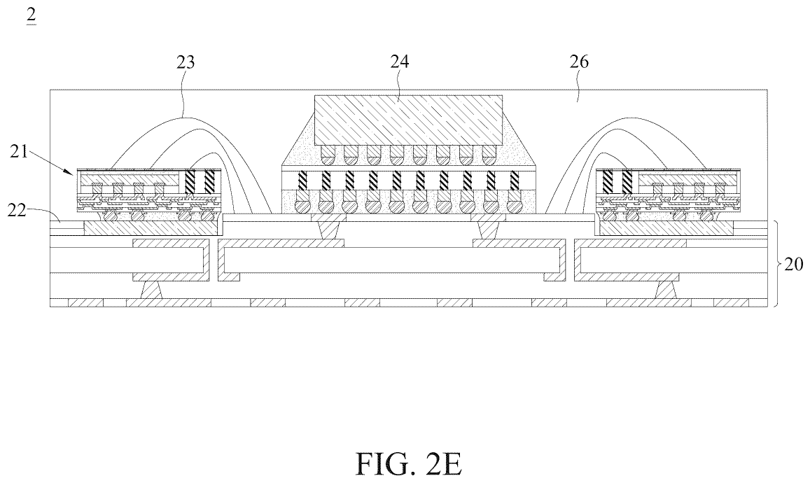

Please refer to FIG. 2A to FIG. 2E, which are schematic cross-sectional views illustrating a method of manufacturing an electronic package 2 according to the present disclosure.

As shown in FIG. 2A, a carrying structure 20 having a first surface 20a and a second surface 20b opposite to the first surface 20a is first provided. In one embodiment, the carrying structure 20 is, for example, a substrate having a core layer or a coreless substrate, wherein the carrying structure 20 includes at least one insulating layer 201 and at least one circuit layer 202 bonded to the insulating layer 201. The insulating layer 201 is made of, for example, dielectric material such as polybenzoxazole (PBO), polyimide (PI), or prepreg (PP). The circuit layer 202 is, for example, a fan-out redistribution layer.

Next, at least one groove 200 is formed at the edge of the first surface 20a of the carrying structure 20 by laser, grinding, or etching. In one embodiment, two grooves 200 are formed.

As shown in FIG. 2B, an optoelectronic device 21 is disposed in the groove 200 of the carrying structure 20. The optoelectronic device 21 includes a package module 210, a semiconductor component 211 disposed in the package module 210, and an optical component 212 connected to the package module 210.

The package module 210 is of, for example, a fan-out stacked package structure (fan-out package-on-package [FO-PoP] structure), and the semiconductor component 211 is, for example, an electronic integrated circuit (EIC) component. The optical component 212 is, for example, an optical chip or an optical chip module (photonic integrated circuit [PIC] module), and the optical chip module includes a coupler, an optical chip, a total reflection mirror, an optical fiber array unit (FAU), etc., wherein the optical component 212 can be bonded to an optical element (optical fiber or optical fiber connector) 22.

In one embodiment, a side of the optoelectronic device 21 having the optical component 212 and the optical element 22 is stably in contact with and bonded to the groove 200 of the carrying structure 20, and another side of the optoelectronic device 21 having the package module 210 faces a direction away from the carrying structure 20.

As shown in FIG. 2C, a plurality of bonding wires 23 are used to electrically connect the carrying structure 20 and the optoelectronic device 21. In one embodiment, one end of each of the bonding wires 23 is connected to the first surface 20a of the carrying structure 20, and the other end of each of the bonding wires 23 is connected to an electrical contact on the surface of the package module 210 of the optoelectronic device 21.

As shown in FIG. 2D, at least one electronic component 24 is bonded and electrically connected to the carrying structure 20.

The electronic component 24 can be, for example, an active component such as a switch chip, a system-on-chip (SOC), a high bandwidth memory (HBM) chip, or other functional chips. Alternatively, the electronic component 24 can also be a passive component such as a resistor, a capacitor, or an inductor. In one embodiment, the electronic component 24 can be bonded and electrically connected to the first surface 20a of the carrying structure 20 via a carrier 25.

The carrier 25 is, for example, a core substrate having at least one circuit layer, a coreless substrate having at least one circuit layer, or an interposer having conductive vias. The electronic component 24 can be electrically connected to the carrier 25 in a flip-chip manner via a plurality of conductive bumps such as solder bumps, copper bumps, or other conductive bumps. The carrier 25 can be bonded and electrically connected to the first surface 20a of the carrying structure 20 via a plurality of conductive components 250.

As shown in FIG. 2E, an encapsulation layer 26 is formed on the carrying structure 20 to encapsulate the electronic component 24, the optoelectronic device 21 and the plurality of bonding wires 23, so that the electronic package 2 of the present disclosure is attained.

The encapsulation layer 26 is made of insulating material, such as polyimide (PI), epoxy molding compound/colloid, or the like.

Via the aforementioned manufacturing process, the present disclosure further provides an electronic package 2, which comprises: a carrying structure 20, an optoelectronic device 21 and an electronic component 24 disposed on the carrying structure 20.

The carrying structure 20 has a first surface 20a and a second surface 20b opposite to the first surface 20a, and the carrying structure 20 includes an insulating layer 201 and a circuit layer 202 bonded to the insulating layer 201. The first surface 20a of the carrying structure 20 is formed with at least one groove 200 to accommodate the optoelectronic device 21.

The optoelectronic device 21 includes a package module 210, a semiconductor component 211 disposed in the package module 210, and an optical component 212 connected to the package module 210. The package module 210 is of a fan-out package-on-package structure, and the semiconductor component 211 is an electronic integrated circuit component. The optical component 212 is an optical chip or an optical chip module, and the optical chip module includes a coupler, an optical chip, a total reflection mirror, an optical fiber array unit, etc., wherein the optical component 212 can be bonded to an optical element (optical fiber or optical fiber connector) 22.

A side of the optoelectronic device 21 having the optical component 212 and the optical element 22 is stably in contact with and bonded to the groove 200 of the carrying structure 20, and another side of the optoelectronic device 21 having the package module 210 faces a direction away from the carrying structure 20, and a plurality of bonding wires 23 are used to electrically connect the carrying structure 20 and the package module 210 of the optoelectronic device 21.

The electronic component 24 can be bonded and electrically connected to the first surface 20a of the carrying structure 20 via the carrier 25. In addition, an encapsulation layer 26 can be formed on the carrying structure 20 and encapsulates the electronic component 24, the optoelectronic device 21 and the plurality of bonding wires 23.

In summary, in the electronic package and the manufacturing method thereof of the present disclosure, the optoelectronic device is placed on the carrying structure in an inverted manner, so that the optical component of the optoelectronic device and the connected optical fiber are placed in the groove at the edge of the carrying structure. At the same time, the electrical contacts on the surface of the package module of the inverted optoelectronic device are electrically connected to the carrying structure via the bonding wires. Therefore, the support and protection of the optical element (optical fiber or optical fiber connector) are enhanced, so that the signal transmission of the optical element can be stable, thereby solving the problems of optical element contact breakage and signal transmission abnormality in the conventional structure. At the same time, there is no need to purchase special equipment, which can reduce product production costs and the feasibility of technical implementation is high.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrying structure having a first surface and a second surface opposite to the first surface;
an optoelectronic device disposed on the first surface of the carrying structure and electrically connected to the carrying structure, wherein the optoelectronic device includes a package module, a semiconductor component disposed in the package module, and an optical component connected to the package module, wherein a side of the optoelectronic device having the optical component is bonded to the carrying structure, and another side of the optoelectronic device having the package module faces a direction away from the carrying structure; and
an electronic component disposed on the first surface of the carrying structure and electrically connected to the carrying structure.

2. The electronic package of claim 1, wherein the first surface of the carrying structure is formed with a groove, and the optoelectronic device is accommodated in the groove.

3. The electronic package of claim 1, wherein the package module is of a fan-out package-on-package structure, the semiconductor component is an electronic integrated circuit component, and the optical component is an optical chip or an optical chip module.

4. The electronic package of claim 3, wherein the optical chip module includes a coupler, an optical chip, a total reflection mirror, or an optical fiber array unit.

5. The electronic package of claim 1, wherein the optical component is bonded to an optical element.

6. The electronic package of claim 1, further comprising a plurality of bonding wires electrically connected to the carrying structure and the optoelectronic device.

7. The electronic package of claim 6, wherein an end of each of the plurality of bonding wires is connected to the first surface of the carrying structure, and another end of each of the plurality of bonding wires is connected to an electrical contact on a surface of the package module of the optoelectronic device.

8. The electronic package of claim 1, wherein the electronic component is bonded and electrically connected to the carrying structure via a carrier.

9. The electronic package of claim 8, wherein the carrier is bonded and electrically connected to the first surface of the carrying structure via a plurality of conductive components.

10. The electronic package of claim 1, further comprising an encapsulation layer formed on the carrying structure for encapsulating the electronic component and the optoelectronic device.

11. A method of manufacturing an electronic package, comprising:
providing a carrying structure having a first surface and a second surface opposite to the first surface;
disposing an optoelectronic device on the first surface of the carrying structure, and electrically connecting the optoelectronic device to the carrying structure, wherein the optoelectronic device includes a package module, a semiconductor component disposed in the package module, and an optical component connected to the package module, wherein a side of the optoelectronic device having the optical component is in contact with and bonded to the carrying structure, and another side of the optoelectronic device having the package module faces a direction away from the carrying structure; and
disposing an electronic component on the first surface of the carrying structure, and electrically connecting the electronic component to the carrying structure.

12. The method of claim 11, wherein the first surface of the carrying structure is formed with a groove, and the optoelectronic device is accommodated in the groove.

13. The method of claim 11, wherein the package module is of a fan-out package-on-package structure, the semiconductor component is an electronic integrated circuit component, and the optical component is an optical chip or an optical chip module.

14. The method of claim 13, wherein the optical chip module includes a coupler, an optical chip, a total reflection mirror, or an optical fiber array unit.

15. The method of claim 11, wherein the optical component is bonded to an optical element.

16. The method of claim 11, further comprising electrically connecting the carrying structure to the optoelectronic device via a plurality of bonding wires.

17. The method of claim 16, wherein an end of each of the plurality of bonding wires is connected to the first surface of the carrying structure, and another end of each of the plurality of bonding wires is connected to an electrical contact on a surface of the package module of the optoelectronic device.

18. The method of claim 11, wherein the electronic component is bonded and electrically connected to the carrying structure via a carrier.

19. The method of claim 18, wherein the carrier is bonded and electrically connected to the first surface of the carrying structure via a plurality of conductive components.

20. The method of claim 11, further comprising forming an encapsulation layer on the carrying structure to encapsulate the electronic component and the optoelectronic device.
